(19) United States
(12) Patent Application Publication
(10) Pub. No.: US 2025/0230324 A1
(43) Pub. Date: Jul. 17, 2025

(54) STRETCHABLE DEVICE

(71) Applicant: Murata Manufacturing Co., Ltd., Nagaokakyo-shi (JP)

(72) Inventor: Takayoshi OBATA, Nagaokakyo-shi (JP)

(21) Appl. No.: 19/171,507

(22) Filed: Apr. 7, 2025

Related U.S. Application Data
(63) Continuation of application No. PCT/JP2024/038179, filed on Oct. 25, 2024.

(30) Foreign Application Priority Data
Nov. 13, 2023 (JP) 2023-193165

(51) Int. Cl. C09D 5/16; H05K 1/02; H05K 3/22

(52) U.S. Cl. CPC C09D 5/16; H05K 1/0283; H05K 3/22

(57) ABSTRACT

A stretchable device including: a stretchable substrate that includes a main surface region extending along a direction different from a thickness direction of the stretchable substrate; and an oil-and-fat barrier layer containing an oil-and-fat material in the main surface region.

### CROSS REFERENCE TO RELATED APPLICATIONS

The present application is a continuation of International application No. PCT/JP2024/038179, filed Oct. 25, 2024, which claims priority to Japanese Patent Application No. 2023-193165, filed Nov. 13, 2023, the entire contents of each of which are incorporated herein by reference.

### TECHNICAL FIELD

The present disclosure relates to a stretchable device.

### BACKGROUND ART

Conventionally, a stretchable device including a stretchable substrate has been known. This stretchable device can be used for, for example, a living body or equipment requiring stretchability.
Patent Document 1: Japanese Patent Application Laid-Open No. 2023-29398

### SUMMARY OF THE DISCLOSURE

Generally, a stretchable device includes a stretchable substrate made of resin. When the stretchable device including such a stretchable substrate is used for a living body or the equipment, a foreign substance, such as sebum, a protein derived from the living body, or machine oil applied to the equipment, may adhere to the stretchable substrate. The inventors of the present application have newly found that if such a foreign substance locally adheres to the stretchable substrate, the stretchable substrate is easily broken at the point of adhesion.

The present disclosure has been made in view of the above problem. That is, a main object of the present disclosure is to provide a stretchable device in which breakage of a stretchable substrate is suitably suppressed.

The inventor of the present application has tried to solve the above problem by addressing the problem in a new direction instead of addressing the problem in an extension of the conventional technology. As a result, the present inventor has invented a stretchable device that achieves the main object.

A stretchable device according to the present disclosure includes: a stretchable substrate that includes a main surface region extending along a direction different from a thickness direction of the stretchable substrate, and an oil-and-fat barrier layer containing an oil-and-fat material in the main surface region.

The stretchable device according to an embodiment of the present disclosure can suitably suppress breakage of the stretchable substrate.

### BRIEF EXPLANATION OF THE DRAWINGS

FIG. 1 is an oblique perspective view schematically illustrating the appearance of a stretchable device according to a first embodiment of the present disclosure.

FIG. 2 is a schematic sectional view illustrating an A-A section of the stretchable device illustrated in FIG. 1.

FIG. 3 is an oblique perspective view schematically illustrating the appearance of a stretchable device including stretchable wiring according to the first embodiment of the present disclosure.

FIG. 4 is a schematic sectional view illustrating a B-B section of the stretchable device illustrated in FIG. 3.

FIG. 5 is a schematic sectional view illustrating a modified aspect of the stretchable device according to the first embodiment of the present disclosure.

FIG. 6 is a schematic sectional view illustrating a modified aspect of the stretchable device according to the first embodiment of the present disclosure.

FIG. 7 is a schematic sectional view illustrating a modified aspect of the stretchable device according to the first embodiment of the present disclosure.

FIG. 8 is an oblique perspective view schematically illustrating a modified aspect of the stretchable device according to the first embodiment of the present disclosure.

FIG. 9 is a schematic sectional view illustrating a C-C section of the stretchable device illustrated in FIG. 8.

FIG. 10 is a schematic sectional view illustrating a modified aspect of the stretchable device according to the first embodiment of the present disclosure.

FIG. 11 is a schematic sectional view illustrating a modified aspect of the stretchable device according to the first embodiment of the present disclosure.

FIG. 12 is a schematic sectional view illustrating a stretchable device according to a second embodiment of the present disclosure.

FIG. 13 is a schematic sectional view illustrating a stretchable device according to a third embodiment of the present disclosure.

FIG. 14A is a schematic sectional view illustrating a modified aspect of the stretchable device according to the third embodiment of the present disclosure.

FIG. 14B is a schematic sectional view illustrating a modified aspect of the stretchable device according to the third embodiment of the present disclosure.

### DESCRIPTION OF THE PREFERRED EMBODIMENTS

Hereinafter, embodiments of the present disclosure will be specifically described. It should be noted that the applicant provides the following description and examples for those skilled in the art to fully understand the present disclosure, and these are not intended to limit the claimed subject matter. That is, the present disclosure is not particularly limited to the preferred aspects and the like described below, and can be appropriately modified and implemented within the scope of the object. Note that, in view of ease of the description and understanding of main points, embodiments, examples, and the like may be presented separately for convenience. However, partial replacement and/or combination of configurations presented in different embodiments and the like can be made. In the description of such embodiments, redundant description of substantially the same matters may be omitted, and only different points may be described. In particular, the same functions and effects by the same configurations may not be mentioned sequentially for each embodiment.

In the present specification, the terms “thickness direction of the stretchable device”, “thickness direction of the stretchable substrate layer”, “lamination direction of the stretchable substrate”, and “lamination direction” can be used interchangeably. Such a direction corresponds to a direction Y in the drawings.

The term “sectional view” or “sectional view shape” referred to in the present specification is based on a form captured from a direction substantially perpendicular to the thickness direction of the stretchable device (in short, a form obtained by cutting along a plane parallel to the thickness direction of the stretchable device). When the stretchable device has a laminated structure including a plurality of stretchable substrate layers, the “sectional view” or “sectional view shape” is based on a form captured from a direction substantially perpendicular to the lamination direction of the stretchable substrates (in short, a form obtained by cutting along a plane parallel to the lamination direction). In addition, the term “plan view” used in the present specification is based on a sketch drawing when an object is viewed from the upper side or lower side along the thickness direction (or lamination direction) of the stretchable device.

In the present specification, “on” an element includes not only a case of being in contact with the upper surface of the element but also a case of not being in contact with the upper surface of the element. That is, “on” an element includes not only an upper position away from the element, that is, an upper position via another object on the element or an upper position spaced apart from the element, but also a directly above position in contact with the element. In addition, the term “on” does not necessarily mean the upper side in the vertical direction. The term “on” merely indicates a relative positional relationship of certain elements.

The various numerical ranges mentioned in the present specification are intended to include the lower and upper limit numerical values themselves, unless otherwise specified. Note that the term “about” means that it can include variations or differences of a few percent, e.g., ±10%.

The terms “vertical” and “substantially vertical” referred to in the present specification do not necessarily have to be perfectly “vertical”, and include an aspect slightly deviated therefrom (e.g., a range of ±10°, such as ±5°, from being perfectly vertical).

In addition, the term “substantial parallel” referred to in the present specification does not necessarily have to be perfectly “parallel”, and includes an aspect slightly deviated therefrom (e.g., a range of ±10°, such as ±5°, from being perfectly parallel).

### [Basic Configuration of Stretchable Device]

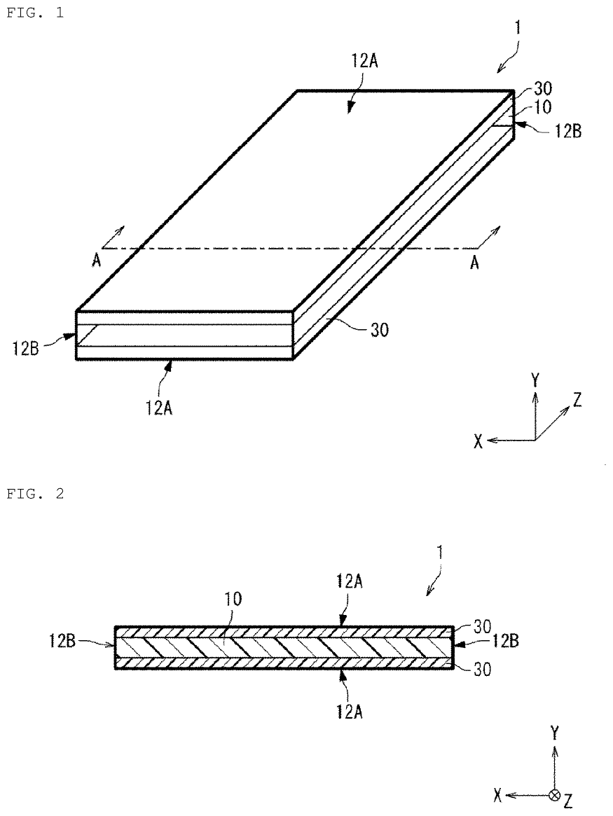

A structure of a stretchable device will be described with reference to FIGS. 1 and 2. FIG. 1 is a perspective view exemplarily illustrating a stretchable device according to an embodiment of the present disclosure. FIG. 2 is an A-A sectional view of the stretchable device of FIG. 1. Note that a sectional view in the present specification illustrates a section parallel to the thickness direction Y of a stretchable device 1.

Hereinafter, main components included in the stretchable device of the present disclosure will be described with reference to FIGS. 1 and 2.

### (Stretchable Substrate 10)

The stretchable device 1 includes at least a stretchable substrate 10. The stretchable substrate 10 (hereinafter, also simply referred to as a “substrate”) may be a sheet-like or film-like stretchable substrate, and may include, for example, a resin material having stretchability. Here, the term “stretchability” in the present specification means, in short, a property of being stretchable, and can also be referred to as stretching property, stretchable property, or the like. More specifically, the term “stretchable” means a property of being capable of stretching from a non-stretched state, which is a normal state with no tensile stress applied, by applying tensile stress and capable of contracting when released from a stretched state. Examples of the resin material used as the stretchable substrate 10 include thermoplastic polyurethane.

The stretchable substrate 10 includes a main surface. In the present specification, the “main surface” of the stretchable substrate is a surface extending in a direction different from the thickness direction Y of the stretchable substrate, and means, for example, a surface extending in a direction X or Z substantially perpendicular to the thickness direction Y of the stretchable substrate. The sheet-like or film-like stretchable substrate 10 may extend along the stretching direction of the stretchable device 1. In such a structure, the “main surface” of the stretchable substrate 10 can also be understood as a surface extending along the stretching direction of the stretchable substrate 10. In an aspect including stretchable wiring to be described later, it can also be understood as a surface extending along the extending direction of the stretchable wiring (see FIG. 3). In the drawings, the stretchable device extending in a specific direction is illustrated for the sake of clarity, but the shape of the stretchable device is not particularly limited. The shape of the stretchable device in plan view is also not particularly limited, and can take various shapes, such as polygons like rectangles (e.g., squares, rectangles, etc.) and triangles; and circular, elliptical, semicircular, crescent, or irregular shapes.

The thickness of the stretchable substrate 10 is not particularly limited, but when emphasis is placed on the stretchability of the device, the thickness is preferably 1 mm or less, more preferably 100 μm or less, and still more preferably 50 μm or less. When emphasis is placed on the mechanical strength of the device, the thickness of the stretchable substrate 10 is preferably 1 μm or more. In addition, in a case where a plurality of stretchable substrates constitutes a laminate, each of the plurality of stretchable substrates to be laminated may have the same thickness, or may have a thickness different from those of the others.

### (Stretchable Wiring 20)

The stretchable device 1 may further include stretchable wiring 20 disposed on the stretchable substrate 10 (see FIG. 3). The stretchable wiring 20 (hereinafter, it is also simply referred to as “wiring”) contains a conductive particle and a resin. Examples of the stretchable wiring 20 include a mixture containing a metal powder, such as Ag (silver), Cu (copper), or Ni (nickel) as the conductive particle, and an elastomer-based resin, such as a silicone resin. The average particle size of the conductive particles is not particularly limited, but is preferably 0.01 μm to 10 μm. In addition, the shape of the conductive particle may be spherical.

In FIG. 3, only the stretchable wiring 20 extending in a specific direction is illustrated for the sake of clarity, but the stretchable wiring 20 may extend in any direction on the main surface and/or in the inside of the stretchable substrate 10. Preferably, the stretchable wiring 20 may extend along the extending direction of the main surface of the stretchable substrate 10. In addition, the stretchable wiring 20 may not be necessarily arranged linearly when viewed from the thickness direction Y of the stretchable substrate 10, and may be arranged, for example, in a curved shape. In addition, the stretchable wiring 20 may not necessarily extend in one direction when viewed from the thickness direction Y. The number of the stretchable wiring 20 is also not particularly limited, and one or a plurality of wiring may be arranged.

### First Embodiment

Based on the contents of the main components of the stretchable device 1 described above, characteristic portions of the stretchable device 1 according to a first embodiment of the present disclosure will be described below. As illustrated in FIGS. 1 and 2, the stretchable device 1 of the present disclosure includes an oil-and-fat barrier layer 30 in a main surface region 12A of the stretchable substrate. The stretchable device 1 includes the oil-and-fat barrier layer 30 positioned in the main surface region 12A of the stretchable substrate. The oil-and-fat barrier layer 30 may be provided to cover the stretchable substrate 10 in the main surface region 12A. In other words, the main surface side of the stretchable substrate 10 may be covered with the oil-and-fat barrier layer 30.

Note that the “main surface region”, the “side surface region”, and the “surface region” in the present specification mean a region on a surface, which is the main surface, the side surface, or the surface including the main surface and the side surface, of the stretchable substrate and a region inside the stretchable substrate within a depth of 3 μm along the thickness direction Y from the surface, respectively. That is, the “main surface region 12A” means a region on the main surface of the stretchable substrate 10 and a region inside the stretchable substrate within a depth of 3 μm along the thickness direction Y from the main surface. The oil-and-fat barrier layer 30 may be positioned in a region on the main surface of the stretchable substrate 10 and/or a surface layer region including the main surface of the stretchable substrate 10.

In short, the “oil-and-fat barrier layer 30” in the present specification is a layer that is positioned in the surface region of the stretchable substrate and mainly contains an oil-and-fat material. The oil-and-fat barrier layer 30 refers to a layer in which an oil-and-fat material is positioned in the surface region of the stretchable substrate 10. More specifically, the oil-and-fat barrier layer 30 contains at least one of an oil-and-fat material having impregnated the inside of the stretchable substrate 10 and an oil-and-fat material positioned on the surface of the stretchable substrate 10 in the surface region of the stretchable substrate 10. The oil-and-fat barrier layer 30 can also be simply referred to as an “oil-and-fat layer”, an “oil-and-fat containing layer”, or the like. Such an oil-and-fat barrier layer 30 is a layer positioned in the surface region including at least the main surface region 12A of the stretchable substrate, and is different from sebum locally adhered by, for example, touching the stretchable device 1.

The stretchable device 1 can be attached to various objects including living bodies, such as human bodies, or equipment. During the use of the stretchable device 1, including attachment of the stretchable device 1, various foreign substances, including sebum from fingers, proteins, and/or machine oil applied to equipment, can locally adhere to the stretchable device 1. The inventors of the present application have newly found that such a locally adhered foreign substance can cause breakage of the stretchable device 1.

As described above, the stretchable substrate 10 included in the stretchable device 1 includes a resin material. When the stretchable substrate 10 stretches, the molecules constituting the stretchable substrate 10 are pulled along the stretching direction, whereby the distance between the molecules constituting the stretchable substrate 10 increases, compared to a normal state (i.e., a non-stretched state). That is, the molecular structure of the stretchable substrate 10 becomes more sparse in the stretched state of the stretchable substrate 10. If a foreign substance adheres to the surface of the stretchable substrate 10 in such a state, a foreign substance can enter between the sparse molecular structures.

The foreign substance having entered the molecular structure can cause inhibition of movement of molecules constituting the stretchable substrate 10 or breakage of the molecular structure. When the movement of the molecule is inhibited, the stretchability of the stretchable substrate 10 can locally decrease, and the uniform stretchability of the entire stretchable substrate 10 can be impaired. If the stretchability of the stretchable substrate 10 is non-uniform, stress can easily concentrate on a point having low stretchability, and as a result, the stretchable substrate 10 can be broken at the point. If the molecular structure of the stretchable substrate 10 is broken in part, the mechanical strength of the stretchable substrate 10 locally decreases, and the stretchable substrate 10 can be broken. As described above, if a foreign substance locally adheres to the surface of the stretchable substrate 10, the adhered foreign substance enters the molecular structure constituting the stretchable substrate 10, and hence the stretchable substrate 10 can be easily broken at the point of adhesion of the foreign substance.

In addressing such a problem, the inventor of the present application has newly found that when the stretchable device 1 includes the oil-and-fat barrier layer 30 in the main surface region 12A of the stretchable substrate, occurrence of breakage of the stretchable substrate 10 associated with adhesion of a foreign substance can be suppressed. As described above, breakage of the stretchable substrate 10 due to adhesion of a foreign substance can be caused by a local decrease in the stretchability and/or mechanical strength of the stretchable substrate 10 at the point of adhesion of the foreign substance adheres.

In the stretchable device 1 of the present disclosure, the stretchable substrate 10 includes the oil-and-fat barrier layer 30 in advance, so that if a foreign substance adheres to the stretchable substrate during use, entry of the foreign substance into the stretchable substrate 10 can be suppressed. Specifically, the oil-and-fat material constituting the oil-and-fat barrier layer 30 is disposed in advance in the main surface region 12A of the stretchable substrate 10, so that if a foreign substance from the outside adheres to the main surface, the foreign substance cannot easily enter the molecular structure of the stretchable substrate 10. As a result, a local change in the molecular structure of the stretchable substrate 10 is suppressed, and the stretchable substrate 10 can maintain more uniform stretchability and mechanical strength as a whole. That is, according to the stretchable device 1 of the present disclosure, a local change in the stretchability and/or mechanical strength of the stretchable substrate 10 caused by adhesion of a foreign substance can be suppressed, so that, as a result, breakage of the stretchable substrate 10 can be suitably suppressed.

As described above, the oil-and-fat barrier layer 30 in the stretchable device 1 of the present disclosure contributes to protecting the stretchable substrate 10 from foreign substances, which can also be referred to as a “protective layer”, a “protective film”, a “coating layer”, or the like.

In a preferred aspect, the oil-and-fat barrier layer 30 may extend in the main surface region 12A of the stretchable substrate. More specifically, the oil-and-fat barrier layer 30 may continuously extend along the main surface region 12A of the stretchable substrate. According to such a structure, the main surface of the stretchable substrate 10 is suitably protected by the oil-and-fat barrier layer 30 extending in the main surface region 12A. Therefore, arrival of a foreign substance onto the main surface of the stretchable substrate 10 and/or entry of the foreign substance into the molecular structure of the stretchable substrate 10 can be suitably suppressed. As a result, a stretchable device that can suppress occurrence of breakage of the stretchable substrate caused by adhesion of a foreign substance can be provided.

The oil-and-fat barrier layer 30 may be continuously provided as described above, and alternatively, may be discontinuously provided. That is, the oil-and-fat barrier layer 30 may continuously extend in the surface region of the stretchable substrate 10, or a plurality of discontinuous oil-and-fat barrier layers 30 may be provided on the surface of the stretchable substrate 10.

In the main surface region 12A, there may be a region where the oil-and-fat barrier layer 30 is not positioned. In other words, the oil-and-fat barrier layer 30 may be provided in a partial region of the main surface region 12A. When viewed from the thickness direction Y of the stretchable substrate, the oil-and-fat barrier layer 30 may be positioned in a range occupying 50% or more, 70% or more, or 90% or more of the area of the main surface region 12A where the oil-and-fat barrier layer 30 is to be positioned. The presence of the oil-and-fat barrier layer 30 in the above-described range can suitably suppress breakage of the stretchable substrate 10. The area of the main surface region 12A when viewed from the thickness direction of the stretchable substrate can also be referred to as the area of the main surface.

The oil-and-fat barrier layer 30 is provided at least in the main surface region 12A of the stretchable substrate 10. In the sheet-like stretchable substrate 10, the main surface can be a surface having the largest area among the plurality of surfaces constituting the stretchable substrate 10. To the main surface that is a wide surface, a foreign substance is more likely to adhere, compared to the other surfaces. Therefore, by providing the oil-and-fat barrier layer 30 in the main surface region 12A, breakage of the stretchable substance 10 caused by adhesion of a foreign substance can be suitably suppressed. As illustrated in FIGS. 1 and 2, the stretchable substrate 10 may have two main surface regions 12A facing each other. In such a structure, the oil-and-fat barrier layer 30 is positioned in at least one main surface region 12A of the two main surface regions 12A facing each other. That is, the oil-and-fat barrier layer 30 may be positioned in either one of the two main surface regions 12A, and alternatively, may be positioned in both of the two main surface regions 12A.

As illustrated in FIGS. 1 and 2, the oil-and-fat barrier layer 30 may be provided in the main surface region 12A of the stretchable substrate not including the stretchable wiring. In the stretchable device 1 of the present disclosure, the oil-and-fat barrier layer 30 can be applied regardless of the presence or absence of the stretchable wiring, and breakage of the stretchable substrate 10 can be suitably suppressed. In such a structure, the oil-and-fat barrier layer 30 may be provided to cover at least a central portion of the main surface region 12A when viewed from the thickness direction Y of the stretchable substrate.

Alternatively, the oil-and-fat barrier layer 30 may be provided on the stretchable substrate 10 including the stretchable wiring 20, as illustrated in FIG. 3. The stretchable substrate 10 may include the stretchable wiring 20 disposed therein, and may include the oil-and-fat barrier layer 30 in at least the main surface region 12A. Preferably, the oil-and-fat barrier layer 30 may be provided in a region overlapping the stretchable wiring 20 when viewed from the thickness direction Y of the stretchable substrate. That is, the stretchable wiring 20 and the oil-and-fat barrier layer 30 may be disposed to overlap each other when viewed from the thickness direction Y of the stretchable substrate. In the stretchable device 1 of the present disclosure, by disposing the oil-and-fat barrier layer 30 in at least the region overlapping the stretchable wiring 20 when viewed from the thickness direction Y, the stretchable substrate 10 positioned in the region overlapping the stretchable wiring 20 can be suitably protected from adhesion of a foreign substance. While the stretchable device 1 is being used, electric signals are generally transmitted with the stretchable wiring 20 disposed on the stretchable substrate 10 interposed therebetween. If breakage of the stretchable substrate 10 occurs in the region overlapping the stretchable wiring 20, the stretchable wiring 20 can be damaged due to the breakage, which can cause an abnormality in transmitting an electric signal. In the stretchable device 1 of the present disclosure, by disposing the oil-and-fat barrier layer 30 in at least the region overlapping the stretchable wiring 20 when viewed from the thickness direction Y in order to protect the stretchable substrate 10 covering the stretchable wiring 20, breakage of the stretchable wiring 20 can be suitably suppressed.

Preferably, the oil-and-fat barrier layer 30 may be provided across the entire main surface of the stretchable substrate 10. In other words, the entire main surface of the stretchable substrate 10 may be covered with the oil-and-fat barrier layer 30. As a result, the entire main surface of the stretchable substrate 10 is suitably protected against adhesion of a foreign substance, so that breakage of the stretchable substrate 10 can be more suitably suppressed.

The oil-and-fat barrier layer 30 can exist in at least one of a surface layer region inside the stretchable substrate 10 and a region on a surface outside the stretchable substrate 10. That is, the oil-and-fat barrier layer 30 may include at least one of a layer present on the inner side of the stretchable substrate 10 and a layer present on the outer side of the stretchable substrate 10. The oil-and-fat barrier layer 30, which contains an oil-and-fat material having impregnated the inner side of the stretchable substrate 10 and is positioned on the inner side of the stretchable substrate 10, is hereinafter referred to as a “first oil-and-fat layer” (see FIGS. 1 to 4). The first oil-and-fat layer can also be referred to as an “inner side oil-and-fat layer”, an “impregnated oil-and-fat layer”, or the like. The oil-and-fat barrier layer 30, which contains an oil-and-fat material positioned on the surface of the stretchable substrate 10 and which is positioned on the surface of the stretchable substrate 10, is hereinafter referred to as a “second oil-and-fat layer” (see FIG. 5). The second oil-and-fat layer can also be referred to as an “outer side oil-and-fat layer”, an “applied oil-and-fat layer”, or the like. That is, the stretchable device 1 of the present disclosure may include an oil-and-fat barrier layer including at least one of the first oil-and-fat layer and the second oil-and-fat layer.

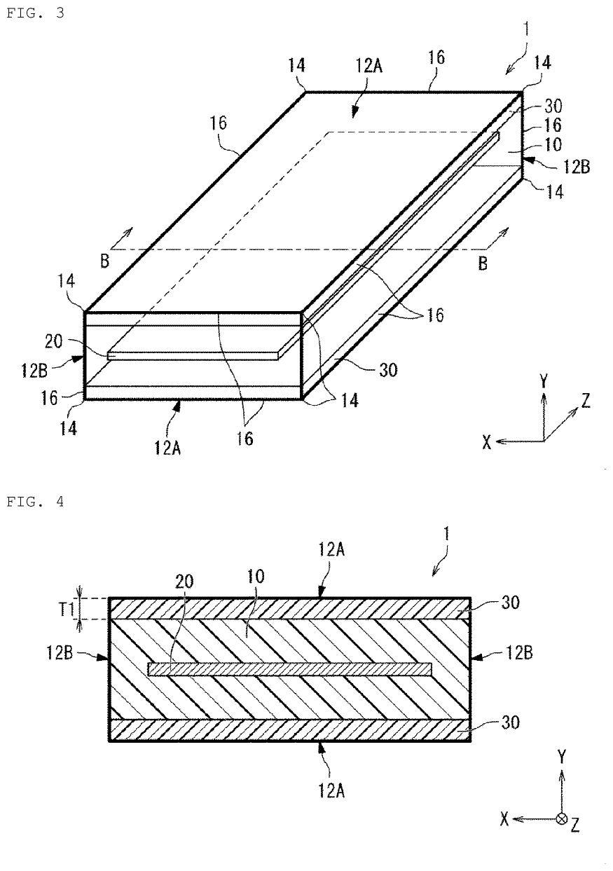

As illustrated in FIG. 4, by providing the first oil-and-fat layer 30 containing the oil-and-fat material having impregnated, the oil-and-fat material can be disposed in the molecular structure positioned in the surface layer of the stretchable substrate 10. Since the oil-and-fat material is disposed in advance in the molecular structure, entry of a foreign substance locally adhered into the molecular structure can be suppressed. Although it should not be construed as being limited to a specific theory, it is presumed that this is because the oil-and-fat material constituting the oil-and-fat barrier layer 30 is interposed in the molecular structure of the stretchable substrate 10 in the surface layer of the stretchable substrate 10, thereby blocking the entry route of foreign substances. Therefore, it is considered that a local change in the stretchability and/or mechanical strength of the stretchable substrate 10 is suppressed, and as a result, breakage of the stretchable substrate 10 can be suitably suppressed.

In addition, the second oil-and-fat layer 30 containing the oil-and-fat material disposed on the surface of the stretchable substrate 10 can suppress arrival of the foreign substance adhered to the stretchable device 1 onto the stretchable substrate 10, as illustrated in FIG. 5. In other words, entry of a foreign substance into the surface of the stretchable substrate can be hindered by the second oil-and-fat layer. As a result, local entry of the foreign substance into the molecular structure of the stretchable substrate can be prevented, so that breakage of the stretchable substrate caused by local adhesion of a foreign substance can be suitably suppressed.

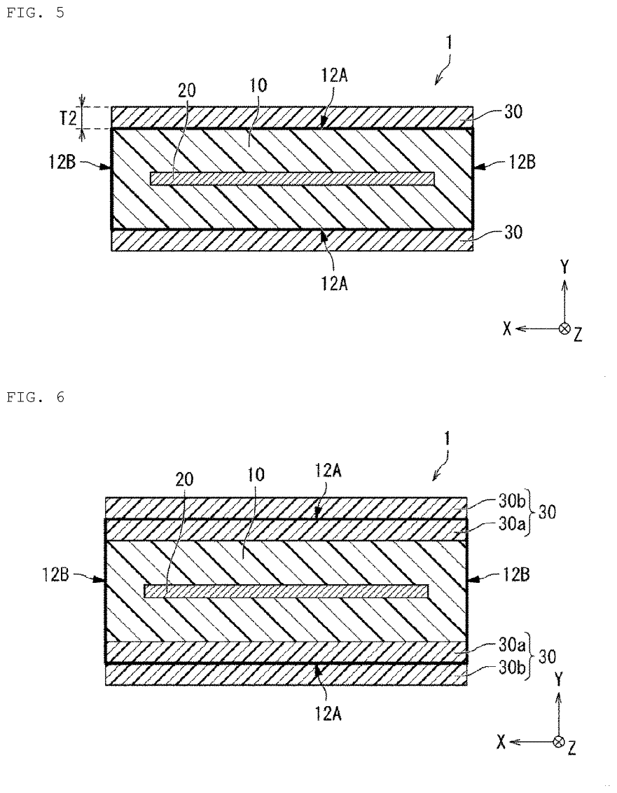

Preferably, the oil-and-fat barrier layer 30 includes at least the first oil-and-fat layer. With the oil-and-fat barrier layer including at least the first oil-and-fat layer, entry of a foreign substance into the stretchable substrate 10 can be suitably avoided. For example, the oil-and-fat barrier layer 30 may include only a first oil-and-fat layer 30a (see FIG. 4), and alternatively, may include both the first oil-and-fat layer 30a and a second oil-and-fat layer 30b (see FIG. 6). The first oil-and-fat layer 30a and the second oil-and-fat layer 30b may overlap each other at least in part when viewed from the thickness direction of the oil-and-fat barrier layer 30. The region, where the first oil-and-fat layer 30a and the second oil-and-fat layer 30b overlap each other when viewed from the thickness direction of the oil-and-fat barrier layer 30, corresponds to a configuration in which, on the surface of the stretchable substrate 10 whose surface layer is impregnated with an oil-and-fat material, an oil-and-fat material is further applied. As a result, the first oil-and-fat layer 30a suppresses entry of a foreign substance into the stretchable substrate 10, and the second oil-and-fat layer 30b can also suppress arrival of a foreign substance onto the surface of the stretchable substrate. As a result, local stress concentration caused by adhesion of a foreign substance in the stretchable substrate 10 can be more suitably suppressed.

In the oil-and-fat barrier layer 30 including both the first oil-and-fat layer 30a and the second oil-and-fat layer 30b, the first oil-and-fat layer 30a and/or the second oil-and-fat layer 30b may be discontinuously positioned. For example, while the first oil-and-fat layer 30a continuously extends, the second oil-and-fat layer 30b may be discontinuous. Alternatively, while the first oil-and-fat layer 30a is discontinuously positioned, the second oil-and-fat layer 30b may continuously extend. Alternatively, both the first oil-and-fat layer 30a and the second oil-and-fat layer 30b may continuously extend. In still another aspect, both the first oil-and-fat layer 30a and the second oil-and-fat layer 30b may be discontinuously positioned. The first oil-and-fat layer 30a and the second oil-and-fat layer 30b, which are discontinuous, may overlap each other at least in part when viewed from the thickness direction of the oil-and-fat barrier layer 30. Thereby, the oil-and-fat barrier layer 30 continuously extending may be formed when viewed macroscopically. For example, the surface region of the stretchable substrate may be covered with at least one of the first oil-and-fat layer 30a and the second oil-and-fat layer 30b.

A thickness T1 of the first oil-and-fat layer may be, for example, 1 μm or more, 1.5 μm or more, or 3 μm or more in sectional view (see FIG. 4). Note that the “thickness of the first oil-and-fat layer” can be understood as the depth of the first oil-and-fat layer heading from the surface of the stretchable substrate 10 toward the inside of the stretchable substrate 10. When the thickness T1 of the first oil-and-fat layer falls within the above-described range, local entry of a foreign substance into the stretchable substrate 10 can be suitably suppressed. For example, the thickness of sebum adhered to the human skin is generally about 0.5 μm. Therefore, when the lower limit of the thickness T1 of the first oil-and-fat layer is as described above, the stretchable substrate 10 can be suitably protected from sebum that can locally adhere to the stretchable device 1 upon contact with the skin occurring, for example, when the skin comes into contact with the stretchable device 1. When emphasis is placed on the stretchability of the stretchable substrate 10 as a whole, the thickness T1 of the first oil-and-fat layer may be 100 μm or less, 70 μm or less, or 40 μm or less.

A thickness T2 of the second oil-and-fat layer may be, for example, 1 μm or more, 1.5 μm or more, or 3 μm or more in sectional view (see FIG. 5). When the thickness T2 of the second oil-and-fat layer falls within the above-described range, arrival of a foreign substance onto the surface of the stretchable substrate 10 can be suitably suppressed. When emphasis is placed on the stretchability of the stretchable substrate 10 as a whole, the thickness T2 of the second oil-and-fat layer may be 100 μm or less, 70 μm or less, or 40 μm or less.

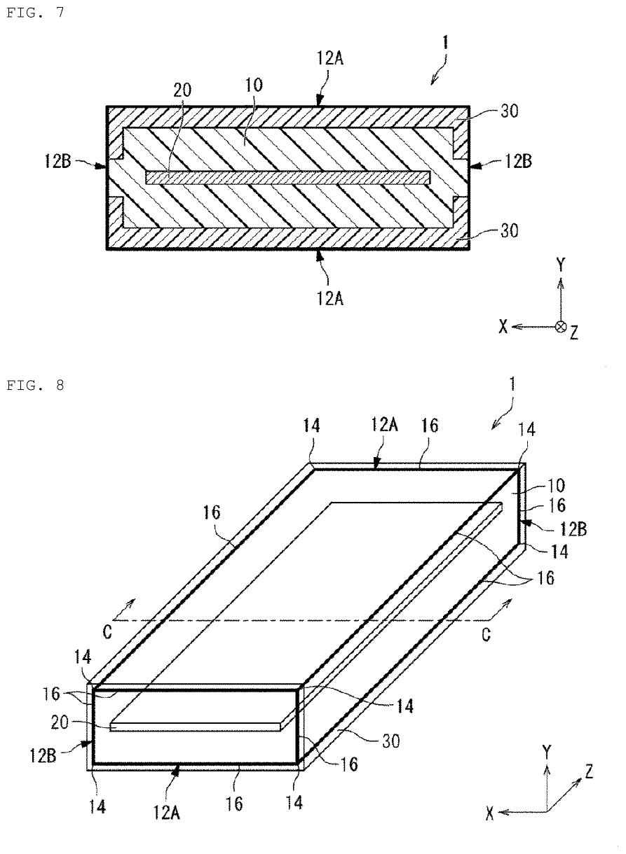

In addition, the stretchable substrate 10 includes side surfaces that connect two main surfaces disposed to face each other, as illustrated in FIG. 7. The oil-and-fat barrier layer 30 may be disposed from the main surface to the side surface of the stretchable substrate 10. That is, the oil-and-fat barrier layer 30 may extend from the main surface region 12A to a side surface region 12B of the stretchable substrate 10. Specifically, the oil-and-fat barrier layer 30 may be provided to cover the entire main surface region 12A and at least a part of the side surface region 12B. In such a structure, in a case where the stretchable substrate 10 has a rectangular sheet shape in sectional view, the oil-and-fat barrier layer 30 can be disposed to also cover the ridge line portion and/or corner portion of the stretchable substrate 10. As a result, the oil-and-fat barrier layer 30 can protect not only the main surface of the stretchable substrate 10 but also the ridge line portion and/or corner portion where stress is likely to concentrate. Therefore, according to the above-described structure, breakage of the stretchable substrate 10 can be more suitably suppressed. Furthermore, the oil-and-fat barrier layer 30 is formed across a plurality of surfaces of the stretchable substrate 10, so that the oil-and-fat barrier layer 30 can be more suitably held by the stretchable substrate 10, compared to a form in which the oil-and-fat barrier layer 30 is formed only on a single surface.

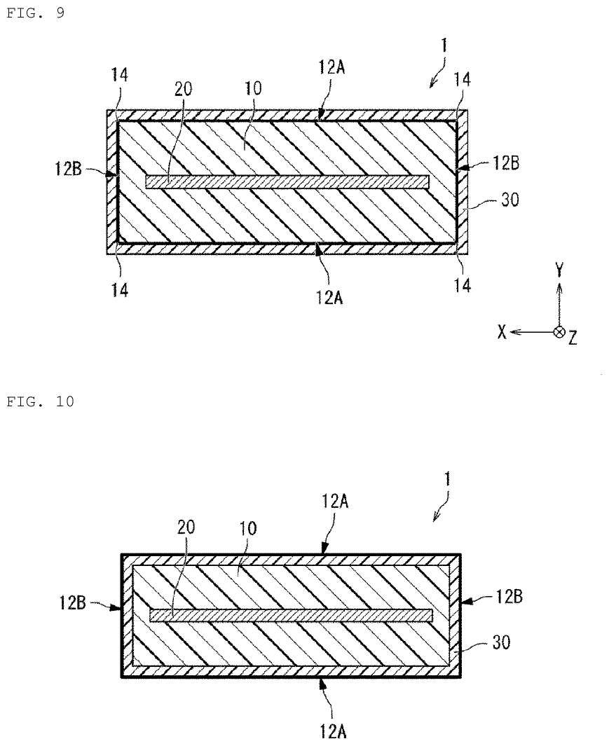

In a preferred aspect, the oil-and-fat barrier layer 30 is disposed to cover the entire outer surface of the stretchable substrate 10 (see FIGS. 8 to 11). That is, the oil-and-fat barrier layer 30 may be provided to surround the stretchable substrate 10. In other words, the stretchable substrate 10 may be covered with the oil-and-fat barrier layer 30 positioned in the surface layer region including the main surface region 12A and the side surface region 12B of the stretchable substrate 10. Such a configuration can also be understood as a configuration in which the oil-and-fat barrier layer 30 extends along the outer contour of the stretchable substrate 10. For example, the oil-and-fat barrier layer 30 may be continuously formed across the entire surface of the stretchable substrate 10. In such a configuration, all of the corner portions 14 and the ridge line portions 16 of the stretchable substrate 10 can be covered with the oil-and-fat barrier layer 30 (see FIG. 8). As a result, the entire stretchable substrate 10 is protected by the oil-and-fat barrier layer 30, which can more suitably suppress breakage of the stretchable substrate 10 caused by adhesion of a foreign substance.

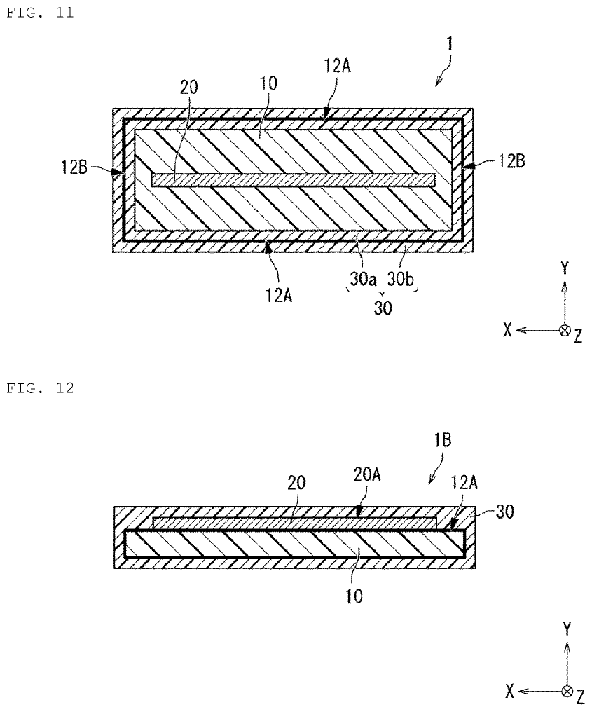

The oil-and-fat material contained in the oil-and-fat barrier layer 30 provided across the entire stretchable substrate 10 may be applied onto the surface of the stretchable substrate 10 in the main surface region 12A and the side surface region 12B of the stretchable substrate (see FIG. 9), or may impregnate the inner side of the stretchable substrate 10 (see FIG. 10). Alternatively, the oil-and-fat barrier layer 30 may include both the first oil-and-fat layer 30a and the second oil-and-fat layer 30b. That is, the oil-and-fat barrier layer 30 may include at least one of the first oil-and-fat layer 30a and the second oil-and-fat layer 30b. The oil-and-fat barrier layer 30 provided in the main surface region 12A and the side surface region 12B does not necessarily have a uniform structure. For example, the oil barrier layers 30 each having a different thickness may be provided in the main surface region 12A and the side surface region 12B. For example, while both the first oil-and-fat layer 30a and the second oil-and-fat layer 30b are provided in the main surface region 12A, only the first oil-and-fat layer 30a may be provided in the side surface region 12B. Thus, the oil-and-fat barrier layers 30 each having a different structure may be formed in the main surface region 12A and the side surface region 12B.

The oil-and-fat material contained in the oil-and-fat barrier layer 30 can be any oil-and-fat material used in fields such as food, feed, cosmetics, medicine, and industry. For example, the oil-and-fat material contained in the oil-and-fat barrier layer 30 may be at least one selected from the group consisting of vegetable oils and fats, animal oils and fats, mineral oils, and synthetic oils. The oil-and-fat material may be in a liquid state or in a solid state.

Examples of the vegetable oils and fats include, but are not particularly limited to, alone or mixed oils of soybean oil, corn oil, cottonseed oil, rapeseed oil, sesame oil, perilla oil, rice oil, sunflower oil, peanut oil, olive oil, palm oil, palm kernel oil, rice germ oil, wheat germ oil, brown rice germ oil, adlay oil, garlic oil, macadamian nut oil, avocado oil, evening primrose oil, flower oil, camellia oil, coconut oil, castor oil, linseed oil, cacao oil, wood wax, jojoba oil, and grape seed oil; and processed fats and oils obtained by subjecting them to curing, fractionation, transesterification, or the like.

Examples of the animal oils and fats include, but are not particularly limited to, fish oil, chicken oil, beef tallow, lard, milk fat, horse oil, snake oil, egg oil, egg yolk oil, turtle oil, mink oil; and processed products of these oils and fats (margarine, shortening, butter, etc.).

Examples of the mineral oils include, but are not particularly limited to, rust preventive oil, cutting oil, engine oil, gear oil, and grease.

Examples of the synthetic oils include, but are merely examples, nonpolar oil such as hydrocarbon oil; silicone oil; and ester oil. Specifically, examples thereof include: hydrocarbon oils such as Vaseline®, solid paraffin, and liquid paraffin; silicone oils such as cyclopentasiloxane; and ester oils such as cetyl ethylhexanoate, ethylhexyl palmitate, isopropyl myristate, isopropyl palmitate, tri(caprylic/capric)glyceryl, and triethylhexanoin.

For example, when the stretchable device 1 is applied to a human body, the oil-and-fat material contained in the oil-and-fat barrier layer 30 is preferably an oil-and-fat material excellent in biocompatibility. For example, when the stretchable device 1 is used in industrial equipment or the like, the oil-and-fat barrier layer 30 preferably contains an oil-and-fat material of the same type as the oil-and-fat material used as a machine oil. As a result, if a machine oil locally adheres during the use of the stretchable device 1, a local change in the stretchability and mechanical strength of the stretchable substrate 10 can be suitably suppressed because the machine oil is equivalent to the component contained in the oil-and-fat barrier layer 30.

### (Method for Manufacturing Stretchable Device)

Hereinafter, an exemplary method for manufacturing a stretchable device according to an embodiment of the present disclosure will be described.

First, a stretchable substrate is prepared. After a stretchable substrate layer is prepared, stretchable wiring may be formed on the main surface of the stretchable substrate layer.

The stretchable wiring may be formed by printing a conductive paste (e.g., a conductive paste containing a mixture of silver and a resin) on the stretchable substrate using screen printing, an inkjet method, or the like. As a result, a desired circuit pattern can be obtained.

After the circuit pattern of the stretchable wiring 20 is formed on the stretchable substrate 10, the conductive paste for stretchable wiring is dried and cured, whereby the stretchable wiring 20 can be formed on the stretchable substrate 10. The printing may be performed not only on one main surface of the stretchable substrate 10 but also on both surfaces including the opposite main surface. In addition, a component, such as an electronic component, can also be mounted on the stretchable wiring 20 as necessary.

Subsequently, another stretchable substrate 10 may be stacked in the thickness direction Y so as to cover the stretchable wiring 20 disposed on the stretchable substrate 10. Thereafter, the stacked stretchable substrates 10 may be, for example, pressed under a predetermined temperature condition, thereby bonding the substrates 10 to each other. As a result, the stretchable substrate 10, including therein the stretchable wiring 20, can be obtained.

Thereafter, an oil-and-fat material is applied to the outer surface of the stretchable substrate 10, whereby the oil-and-fat barrier layer 30 is formed. For example, an oil-and-fat material that can impregnate the stretchable substrate 10 may be applied to the outer surface of the stretchable substrate 10 and it is left for a predetermined time (e.g., 1 second or more), thereby impregnating the surface layer of the stretchable substrate 10 with the oil-and-fat material. The method for applying the oil-and-fat is not particularly limited, and a known application method can be applied. Examples of the application method include a roll coater method, a spray method, and a dip method.

In an embodiment, the surface layer of the stretchable substrate 10 may be impregnated with all of the applied oil-and-fat material. Alternatively, the oil-and-fat material may be held on the surface of the stretchable substrate 10 without the inside of the stretchable substrate 10 impregnated with the oil-and-fat material. That is, only the first oil-and-fat layer may be formed to only contain the oil-and-fat material having impregnated the stretchable substrate 10 (see FIG. 9), or only the second oil-and-fat layer may be formed by holding the oil-and-fat material on the surface without being impregnated with the oil-and-fat material (see FIG. 10). For example, the oil-and-fat material that does not impregnate the stretchable substrate 10 is applied onto the surface of the stretchable substrate 10, whereby the second oil-and-fat layer may be formed. Alternatively, a part of the applied oil-and-fat material may remain on the stretchable substrate 10 without impregnating all of the applied oil-and-fat material. Alternatively, both the first oil-and-fat layer and the second oil-and-fat layer may be formed (see FIG. 11).

### Second Embodiment

Next, a stretchable device 1B according to a second embodiment will be described. The stretchable device 1B is different from the stretchable device 1 according to the first embodiment in that stretchable wiring 20 is disposed on the surface of a stretchable substrate 10, not inside the stretchable substrate 10, and an oil-and-fat barrier layer 30 is provided to cover the stretchable wiring 20.

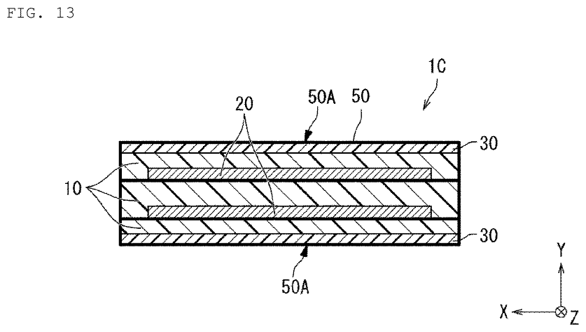

FIG. 12 is a sectional view of the stretchable device 1B according to the second embodiment. As illustrated, the stretchable device 1B may include the stretchable wiring 20 disposed on the outer surface of the stretchable substrate 10. In such a structure, the oil-and-fat barrier layer 30 may be provided to cover the stretchable wiring 20 positioned on the stretchable substrate 10. The stretchable wiring 20 may include the oil-and-fat barrier layer 30 on an outer surface 20A not in contact with the stretchable substrate 10. The oil-and-fat barrier layer 30 may integrally surround the stretchable substrate 10 and the stretchable wiring 20 positioned on the stretchable substrate 10. If the stretchability and mechanical strength of the stretchable wiring 20 are locally changed due to adhesion and entry of a foreign substance, breakage associated with stress concentration can occur, similarly to the stretchable substrate 10. According to the above-described configuration, by providing the oil-and-fat barrier layer 30 covering the stretchable wiring 20, the stretchable wiring 20 positioned outside the stretchable substrate 10, not inside the stretchable substrate 10, can also be suitably protected against adhesion of a foreign substance.

For example, the surface layer of the stretchable wiring 20 disposed on the outer surface of the stretchable substrate may also be impregnated with the oil-and-fat material constituting the oil-and-fat barrier layer 30. As a result, the oil-and-fat barrier layer 30 is suitably held on the stretchable wiring, and the stretchable wiring 20 can be suitably protected from a foreign substance.

### Third Embodiment

Next, a stretchable device 1C according to a third embodiment will be described. The stretchable device 1C is different from the stretchable device 1 according to the first embodiment in that a laminate 50, in which a plurality of stretchable substrates 10 are laminated, is included.

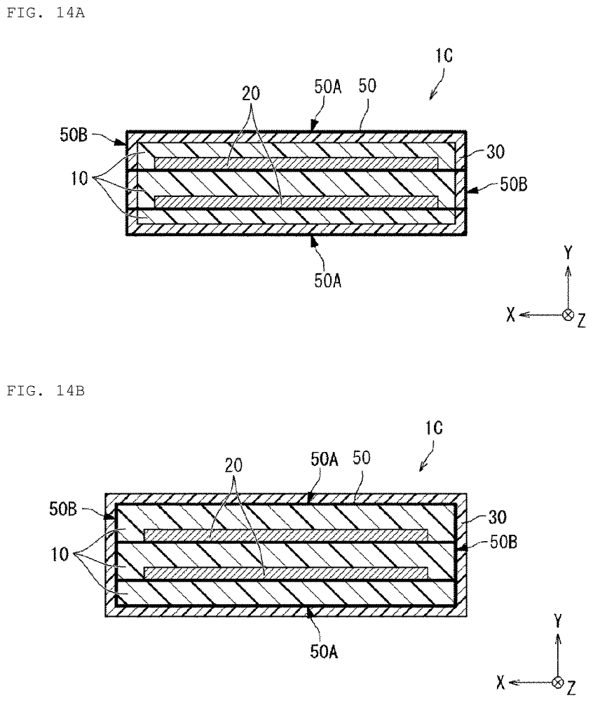

FIGS. 13, 14A, and 14B are schematic sectional views of the stretchable device 1C according to the third embodiment. The stretchable substrates 10 may be laminated on each other in the thickness direction Y. More specifically, the plurality of stretchable substrates 10 may have a multilayer structure in which they are laminated to face their main surfaces each other. That is, the plurality of stretchable substrates 10 may form the laminate 50 by being laminated in the thickness direction Y of the stretchable substrate. Note that the number of the stretchable substrates 10 to be laminated is not particularly limited.

In such a structure, an oil-and-fat barrier layer 30 may be positioned in a main surface region 50A of the stretchable substrate constituting the outer surface of the laminate 50. More specifically, the oil-and-fat barrier layer 30 may be positioned in an upper main surface region of the stretchable substrate 10 positioned in the uppermost part of the laminate 50 and/or in a lower main surface region of the stretchable substrate positioned in the lowermost part of the laminate 50. That is, it can be understood that the oil-and-fat barrier layer 30 is positioned in the main surface region 50A of the outer surface of the laminate 50. According to such a structure, the main surface region 50A of the laminate 50 is protected by the oil-and-fat barrier layer 30, so that breakage of the stretchable substrate 10 caused by adhesion of a foreign substance can be suitably suppressed.

The oil-and-fat barrier layer 30 may be disposed in a side surface region of the stretchable substrate 10 constituting the outer surface of the laminate 50 (see FIGS. 14A and 14B). The oil-and-fat barrier layer 30 may extend from the main surface region 50A of the stretchable substrate 10 positioned in the uppermost part and/or the lowermost part to a side surface region 50B continuous with the main surface region 50A. Preferably, the entire laminate 50 may be covered with the oil-and-fat barrier layer 30 continuously provided across the outer surface of the laminate 50. It can also be understood that such an oil-and-fat barrier layer 30 constitutes the outermost layer of the stretchable device by continuously covering the outer surface of the laminate 50. According to the above-described structure, influence of adhesion of a foreign substance can be suitably reduced across the entire stretchable device 1C including the laminate 50.

The oil-and-fat barrier layer 30 may include at least one of a first oil-and-fat layer (see FIG. 14A) containing an oil-and-fat material having impregnated the inside of the surface of the stretchable substrate 10 constituting the outer surface of the laminate 50 and a second oil-and-fat layer (see FIG. 14B) containing an oil-and-fat material present on the outer surface of the laminate 50. Preferably, the oil-and-fat barrier layer 30 covering the laminate 50 may include at least the first oil-and-fat layer. For example, the oil-and-fat material contained in the first oil-and-fat layer may enter a gap between the stretchable substances 10 adjacent to each other on the outer surface side of the laminate 50. As a result, a local decrease in the stretchability and/or mechanical strength of the stretchable substrate 10, caused by entry of a foreign substance from the gap between the laminated stretchable substances 10, can be suitably suppressed.

Although the embodiments of the present disclosure have been described above, typical examples have been only illustrated. Those skilled in the art will easily understand that the present disclosure is not limited thereto, and various aspects are conceivable within a scope that does not alter the gist of the present disclosure.

For example, the stretchable device may include a portion not including the oil-and-fat barrier layer 30 in the main surface region (alternatively, the main surface region of the laminate when the stretchable device has a laminated structure) of the stretchable substrate 10. For example, in a portion where the stretchability is locally decreased in the stretchable substrate 10, like a portion overlapping, when viewed from the thickness direction Y of the stretchable substrate, a member inferior in stretchability to the stretchable substrate 10, such as an electronic component, the oil-and-fat barrier layer 30 may not be provided. That is, the oil-and-fat barrier layer 30 may be positioned in a main surface region excluding a portion overlapping, when viewed in the thickness direction Y of the stretchable substrate, a member such as an electronic component provided on the stretchable substrate 10. According to such a configuration, breakage of the stretchable substrate 10 caused by adhesion of a foreign substance can be suitably suppressed in the stretchable substrate 10 around the electronic component.

The oil-and-fat barrier layer 30 can have a function of slightly reducing the stretchability of the stretchable substrate 10. Therefore, by providing the oil-and-fat barrier layer 30 in a region excluding a portion having low stretchability in a stretchable device whose stretchability is locally decreased by mounting a component or the like, the stretchability of the stretchable substrate 10 in the portion where the oil-and-fat barrier layer 30 is provided can be slightly reduced. Therefore, the difference in the stretchability of the stretchable substrate 10 between a component mounting portion and a component non-mounting portion can be reduced, and a local decrease in the stretchability of the stretchable substrate 10 in the component mounting portion can be alleviated. That is, by selecting arrangement of the oil-and-fat barrier layer according to the difference in the stretchability of the stretchable device, the stretchability of the stretchable device as a whole can be adjusted. As a result, the stretchable device can have more uniform stretchability as a whole, and occurrence of breakage of the stretchable substrate 10 caused by a local decrease in stretchability can be suitably suppressed.

Note that an embodiment of the present disclosure as described above includes the following preferred aspects.

<1> A stretchable device including: a stretchable substrate that includes a main surface region extending along a direction different from a thickness direction of the stretchable substrate, and an oil-and-fat barrier layer containing an oil-and-fat material in the main surface region.

<2> The stretchable device according to <1>, in which the oil-and-fat barrier layer extends along the main surface region.

<3> The stretchable device according to <1> or <2>, in which the oil-and-fat barrier layer includes a first oil-and-fat barrier layer on an inner side of the stretchable substrate, and the first oil-and-fat barrier layer contains an oil-and-fat material inside the stretchable substrate.

<4> The stretchable device according to <3>, in which the first oil-and-fat barrier layer has a thickness of 1 μm to 100 μm in a sectional view thereof.

<5> The stretchable device according to any one of <1> to <4>, in which the oil-and-fat barrier layer includes a second oil-and-fat barrier layer on an outer surface of the stretchable substrate, and the second oil-and-fat barrier layer contains an oil-and-fat material on the outer surface of the stretchable substrate.

<6> The stretchable device according to <5>, in which the second oil-and-fat barrier layer has a thickness of 1 μm to 100 μm in a sectional view thereof.

<7> The stretchable device according to any one of <1> to <6>, further including stretchable wiring on the stretchable substrate, in which the oil-and-fat barrier layer is in the main surface region overlapping at least the stretchable wiring when viewed in the thickness direction of the stretchable substrate.

<8> The stretchable device according to any one of <1> to <7>, in which the oil-and-fat barrier layer extends across an entirety of the main surface region.

<9> The stretchable device according to any one of <1> to <8>, in which the main surface region is a first main surface region, the stretchable substrate includes a second main surface region facing the first main surface region and a side surface region between the first main surface region and the second main surface region, and the oil-and-fat barrier layer extends from the first main surface region to the side surface region.

<10> The stretchable device according to any one of <1> to <9>, in which the oil-and-fat barrier layer is continuous across an entire outer surface region of the stretchable substrate.

<11> The stretchable device according to any one of <1> to <10>, in which the stretchable substrate is surrounded by the oil-and-fat barrier layer.

<12> The stretchable device according to any one of <1> to <11>, further including stretchable wiring on the outer surface of the stretchable substrate in the main surface region, in which the oil-and-fat barrier layer integrally covers the main surface region and the stretchable wiring.

<13> The stretchable device according to any one of <1> to <12>, including a laminate including a plurality of the stretchable substrates laminated on each other, in which the oil-and-fat barrier layer is in the main surface region of a stretchable substrate among the plurality of stretchable substrates constituting an outer surface of the laminate.

<14> The stretchable device according to <13>, in which among the plurality of the stretchable substrates, the stretchable substrate including a surface constituting the outer surface of the laminate includes the oil-and-fat barrier layer continuous across an entirety of the surface constituting the outer surface.

<15> The stretchable device according to <13> or <14>, in which the laminate is surrounded by the oil-and-fat barrier layer.

<16> The stretchable device according to any one of <1> to <15>, in which the oil-and-fat material selected from at least one of vegetable oils and fats, animal oils and fats, mineral oils, and synthetic oils.

Note that the effects and the like described above are merely one example. Therefore, the present disclosure is not limited to the above matters, and may have additional effects.

### DESCRIPTION OF REFERENCE SYMBOLS

1: Stretchable device
10: Stretchable substrate
12A: Main surface region of stretchable substrate
12B: Side surface region of stretchable substrate
14: Corner portion
16: Ridge line portion
20: Stretchable wiring
30: Oil-and-fat barrier layer
50: Laminate
50A: Main surface region of laminate
50B: Side surface region of laminate

1. A stretchable device comprising:
a stretchable substrate that includes a main surface region extending along a direction different from a thickness direction of the stretchable substrate; and
an oil-and-fat barrier layer containing an oil-and-fat material in the main surface region.

2. The stretchable device according to claim 1, wherein the oil-and-fat barrier layer extends along the main surface region.

3. The stretchable device according to claim 1, wherein the oil-and-fat material of the oil-and-fat barrier layer is present inside the stretchable substrate.

4. The stretchable device according to claim 1, wherein the oil-and-fat material of the oil-and-fat barrier layer is on an outer surface of the stretchable substrate.

5. The stretchable device according to claim 1, wherein
the oil-and-fat barrier layer includes a first oil-and-fat barrier layer on an inner side of the stretchable substrate, and
the first oil-and-fat barrier layer contains an oil-and-fat material inside the stretchable substrate.

6. The stretchable device according to claim 5, wherein the first oil-and-fat barrier layer has a thickness of 1 μm to 100 μm in a sectional view thereof.

7. The stretchable device according to claim 5, wherein
the oil-and-fat barrier layer includes a second oil-and-fat barrier layer on an outer surface of the stretchable substrate, and
the second oil-and-fat barrier layer contains an oil-and-fat material on the outer surface of the stretchable substrate.

8. The stretchable device according to claim 7, wherein the second oil-and-fat barrier layer has a thickness of 1 μm to 100 μm in a sectional view thereof.

9. The stretchable device according to claim 1, further comprising stretchable wiring on the stretchable substrate.

10. The stretchable device according to claim 9, wherein the oil-and-fat barrier layer is in the main surface region overlapping at least the stretchable wiring when viewed in the thickness direction of the stretchable substrate.

11. The stretchable device according to claim 1, wherein the oil-and-fat barrier layer extends across an entirety of the main surface region.

12. The stretchable device according to claim 1, wherein
the main surface region is a first main surface region,
the stretchable substrate includes a second main surface region facing the first main surface region and a side surface region between the first main surface region and the second main surface region, and
the oil-and-fat barrier layer extends from the first main surface region to the side surface region.

13. The stretchable device according to claim 12, wherein the oil-and-fat barrier layer extends in the second main surface region.

14. The stretchable device according to claim 1, wherein the oil-and-fat barrier layer is continuous across an entire outer surface region of the stretchable substrate.

15. The stretchable device according to claim 1, wherein the stretchable substrate is surrounded by the oil-and-fat barrier layer.

16. The stretchable device according to claim 1, further comprising:
stretchable wiring on an outer surface of the stretchable substrate in the main surface region, wherein
the oil-and-fat barrier layer covers the main surface region and the stretchable wiring.

17. The stretchable device according to claim 1, comprising a laminate including a plurality of the stretchable substrates laminated on each other, wherein
the oil-and-fat barrier layer is in the main surface region of a stretchable substrate among the plurality of stretchable substrates constituting an outer surface of the laminate.

18. The stretchable device according to claim 17, wherein among the plurality of the stretchable substrates, the stretchable substrate including the surface constituting the outer surface of the laminate includes the oil-and-fat barrier layer continuous across an entirety of the surface constituting the outer surface.

19. The stretchable device according to claim 17, wherein the laminate is surrounded by the oil-and-fat barrier layer.

20. The stretchable device according to claim 1, wherein the oil-and-fat material is selected from at least one of vegetable oils and fats, animal oils and fats, mineral oils, and synthetic oils.
